(19) United States
(12) Patent Application Publication
(10) Pub. No.: US 2022/0384632 A1
(43) Pub. Date: Dec. 1, 2022

(54) NITRIDE SEMICONDUCTOR DEVICE AND MANUFACTURING METHOD THEREOF

(71) Applicant: United Microelectronics Corp., Hsinchu (TW)

(72) Inventors: Chih Tung Yeh, Taoyuan City (TW); Wen-Jung Liao, Hsinchu City (TW)

(73) Assignee: United Microelectronics Corp., Hsinchu (TW)

(21) Appl. No.: 17/365,996

(22) Filed: Jul. 1, 2021

(30) Foreign Application Priority Data
May 25, 2021 (CN) 202110569951.0

(51) Int. Cl. H01L 29/778; H01L 29/66; H01L 29/51

(52) U.S. Cl. CPC H01L 29/7787; H01L 29/66462; H01L 29/517

(57) ABSTRACT

Provided are a nitride semiconductor device and a manufacturing method thereof. The nitride semiconductor device includes a substrate, a first nitride semiconductor layer, a second nitride semiconductor layer, a metal layer and a dielectric layer. The first nitride semiconductor layer is disposed on the substrate. The second nitride semiconductor layer is disposed on the first nitride semiconductor layer and has a trench. The trench exposes a part of the first nitride semiconductor layer. The metal layer is disposed in the trench. The dielectric layer is disposed in the trench and located between the metal layer and the first nitride semiconductor layer.

### CROSS-REFERENCE TO RELATED APPLICATION

This application claims the priority benefit of China application 1 no. 202110569951.0, filed on May 25, 2021. The entirety of the above-mentioned patent application is hereby incorporated by reference herein and made a part of this specification.

### BACKGROUND

### Technical Field

The disclosure relates to a semiconductor device and a manufacturing method thereof, and more particularly, to a nitride semiconductor device and a manufacturing method thereof.

### Description of Related Art

In order to enable semiconductor devices to have low on-resistance, high switching frequency, high breakdown voltage, and high-temperature operation, etc., gallium nitride (GaN) semiconductor devices are currently one of the most eye-catching options. In the process of manufacturing the nitride semiconductor device, the surface state of gallium nitride high electron mobility transistor (HEMT) is very critical. During the manufacturing process, any surface defects/damages will cause the occurrence of dangling bonds, thereby having a significant impact on the performance of the formed device.

### SUMMARY

The disclosure provides a nitride semiconductor device. A dielectric layer is disposed between a metal layer and a nitride semiconductor layer.

The disclosure provides a manufacturing method of a nitride semiconductor device. A dielectric layer is formed between a metal layer and a nitride semiconductor layer.

The nitride semiconductor device of the disclosure includes a substrate, a first nitride semiconductor layer, a second nitride semiconductor layer, a metal layer, and a dielectric layer. The first nitride semiconductor layer is disposed on the substrate. The second nitride semiconductor layer is disposed on the first nitride semiconductor layer and has a trench. The trench exposes a part of the first nitride semiconductor layer. The metal layer is disposed in the trench. The dielectric layer is disposed in the trench and located between the metal layer and the first nitride semiconductor layer.

In the nitride semiconductor device according to an embodiment of the disclosure, a thickness of the dielectric layer does not exceed 2 nm.

In the nitride semiconductor device according to an embodiment of the disclosure, a material of the dielectric layer includes Al₂O₃, SiN, SiO₂, or a combination thereof.

In the nitride semiconductor device according to an embodiment of the disclosure, a material of the metal layer includes Ti, Al, or a combination thereof.

In the nitride semiconductor device according to an embodiment of the disclosure, a material of the first nitride semiconductor layer includes GaN.

In the nitride semiconductor device according to an embodiment of the disclosure, a material of the second nitride semiconductor layer includes AlGaN.

In an embodiment of the disclosure, the nitride semiconductor device further includes a third nitride semiconductor layer disposed between the first nitride semiconductor layer and the second nitride semiconductor layer.

In the nitride semiconductor device according to an embodiment of the disclosure, a material of the third nitride semiconductor layer includes GaN.

The manufacturing method of the nitride semiconductor device of the disclosure includes the following steps. A first nitride semiconductor layer is formed on a substrate. A dielectric layer is formed on the first nitride semiconductor layer. A second nitride semiconductor layer is grown on the first nitride semiconductor layer. The second nitride semiconductor layer has a trench exposing the dielectric layer. A metal layer is formed on the trench.

In the manufacturing method of the nitride semiconductor device according to an embodiment of the disclosure, a thickness of the dielectric layer does not exceed 2 nm.

In the manufacturing method of the nitride semiconductor device according to an embodiment of the disclosure, a material of the dielectric layer includes Al₂O₃, SiN, SiO₂, or a combination thereof.

In the manufacturing method of the nitride semiconductor device according to an embodiment of the disclosure, a material of the metal layer includes Ti, Al, or a combination thereof.

In the manufacturing method of the nitride semiconductor device according to an embodiment of the disclosure, a material of the first nitride semiconductor layer includes GaN.

In the manufacturing method of the nitride semiconductor device according to an embodiment of the disclosure, a material of the second nitride semiconductor layer includes AlGaN.

In the manufacturing method of the nitride semiconductor device according to an embodiment of the disclosure, after forming the dielectric layer and before forming the second nitride semiconductor layer, the manufacturing method further includes forming a third nitride semiconductor layer on the substrate, and the third nitride semiconductor layer has a the trench exposing the dielectric layer.

In the manufacturing method of the nitride semiconductor device according to an embodiment of the disclosure, a material of the third nitride semiconductor layer includes GaN.

In the manufacturing method of the nitride semiconductor device according to an embodiment of the disclosure, after forming the second nitride semiconductor layer and before forming the metal layer, the manufacturing method further includes removing the dielectric layer.

In the manufacturing method of the nitride semiconductor device according to an embodiment of the disclosure, a method of removing the dielectric layer includes a wet etching process.

In the manufacturing method of the nitride semiconductor device according to an embodiment of the disclosure, a method of forming the dielectric layer includes the following steps. A dielectric material layer is formed on the first nitride semiconductor layer. The dielectric material layer is patterned by using the wet etching process.

The method of forming the dielectric layer includes the following steps. The dielectric material layer is formed on the first nitride semiconductor layer. The dielectric material layer is patterned by using a dry etching process.

Based on the above, in the disclosure, by forming the dielectric layer as a protective layer on a surface of the nitride semiconductor layer in a region where an ohmic contact is to be formed, the surface may not be damaged in the subsequent manufacturing process, and has no defect/damage. In addition, with the dielectric layer, another nitride semiconductor layer may be directly formed on the nitride semiconductor layer, and the another nitride semiconductor layer may have the trench exposing the dielectric layer without an etching process, so as to ensure that the surface of the nitride semiconductor layer in the region where the ohmic contact is to be formed has no defect/damage.

In order for the aforementioned features and advantages of the disclosure to be more comprehensible, embodiments accompanied with drawings are described in detail below.

### BRIEF DESCRIPTION OF THE DRAWINGS

FIGS. 1A to 1D are schematic cross-sectional views of a manufacturing process of a nitride semiconductor device according to the first embodiment of the disclosure.

FIGS. 2A to 2B are schematic cross-sectional views of a manufacturing process of a nitride semiconductor device according to the second embodiment of the disclosure.

FIGS. 3A to 3B are schematic cross-sectional views of a manufacturing process of a nitride semiconductor device according to the third embodiment of the disclosure.

### DETAILED DESCRIPTION OF DISCLOSED EMBODIMENTS

The embodiments are described in detail below with reference to the accompanying drawings, but the provided embodiments are not intended to limit the scope of the disclosure. In addition, the drawings are drawn only for the purpose of description, and are not drawn according to original sizes. For ease of understanding, the same elements in the following description will be denoted by the same reference numerals.

Terms such as “include”, “comprise”, and “have” used herein are all inclusive terms, which also refers to “including but not limited to”.

Terms such as “first” and “second” are only used to distinguish the elements from each other, and do not limit the order or importance of the elements when they are used to describe elements herein. Therefore, in some cases, the first element may also be referred to as the second element, and the second element may also be referred to as the first element, and this does not deviate from the scope of the disclosure.

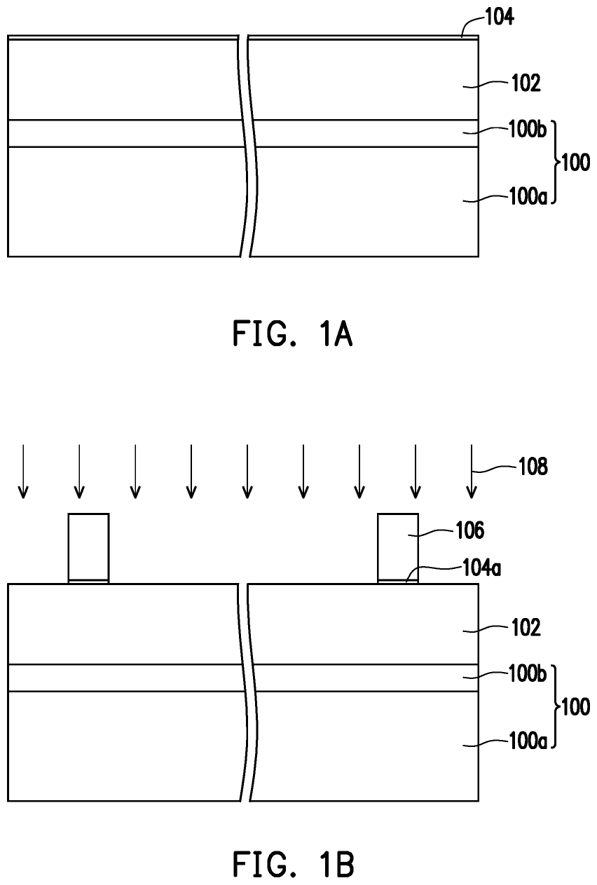

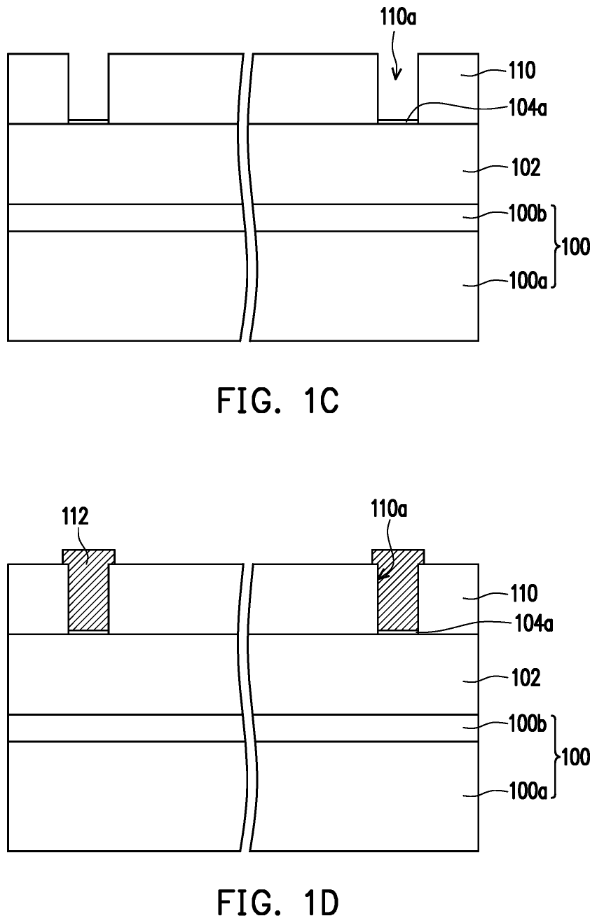

FIGS. 1A to 1D are schematic cross-sectional views of a manufacturing process of a nitride semiconductor device according to the first embodiment of the disclosure.

First, referring to FIG. 1A, a substrate 100 is provided. In this embodiment, the substrate 100 includes a base 100a and a nucleation layer 100b formed on the base 100a, but the disclosure is not limited thereto. The substrate 100 is, for example, a silicon (Si) substrate, a silicon carbide (SiC) substrate, a sapphire substrate, or a gallium nitride (GaN) substrate. A material of the nucleation layer 100b is, for example, a group III-V semiconductor material, such as AlN, GaN, AlGaN, or a combination thereof. Then, a first nitride semiconductor layer 102 is formed on the substrate 100. A material of the first nitride semiconductor layer 102 is, for example, the group III-V semiconductor material, such as GaN. When a nitride semiconductor device to be formed is a transistor, the first nitride semiconductor layer 102 may be used as a channel layer in the transistor. Next, a dielectric material layer 104 is formed on the first nitride semiconductor layer 102. A material of the dielectric material layer 104 is, for example, Al₂O₃, SiN, SiO₂, or a combination thereof. A method of forming the dielectric material layer 104 is, for example, a chemical vapor deposition (CVD) process or an atomic layer deposition (ALD) process. A thickness of the dielectric material layer 104 does not exceed 2 nm. For example, when the material of the dielectric material layer 104 is Al₂O₃, the thickness of the dielectric material layer 104 does not exceed 1 nm, for example. When the material of the dielectric material layer 104 is SiN, the thickness of the dielectric material layer 104 is, for example, between 1.5 nm and 2 nm. When the material of the dielectric material layer 104 is SiO₂, the thickness of the dielectric material layer 104 is, for example, between 1 nm and 2 nm.

Then, referring to FIG. 1B, a patterning process is performed on the dielectric material layer 104 to form a dielectric layer 104a. In this embodiment, a patterned photoresist layer 106 is formed on the dielectric material layer 104. The patterned photoresist layer 106 covers a region where a trench is to be formed in the first nitride semiconductor layer 102. Next, a dry etching process 108 is performed to remove the dielectric material layer 104 that is not covered by the patterned photoresist layer 106, so as to form the dielectric layer 104a. At this time, since the region where the trench is to be formed in the first nitride semiconductor layer 102 is covered by the dielectric layer 104a, the first nitride semiconductor layer 102 in the region may have a smooth surface, that is, there is no defect/damage on the surface. In other words, in this embodiment, the dielectric layer 104a may have an effect of a protective layer. In another embodiment, the dry etching process 108 may be replaced by a wet etching process, so that the first nitride semiconductor layer 102 may have a relatively smooth surface.

Next, referring to FIG. 1C, the patterned photoresist layer 106 is removed. Then, a second nitride semiconductor layer 110 is formed on the first nitride semiconductor layer 102. The second nitride semiconductor layer 110 has a trench 110a exposing the dielectric layer 104a. A material of the second nitride semiconductor layer 110 is, for example, the group III-V semiconductor material, such as AlGaN. When the nitride semiconductor device to be formed is the transistor, the second nitride semiconductor layer 110 may be used as a barrier layer in the transistor. In detail, in this embodiment, a method of forming the second nitride semiconductor layer 110 is, for example, an epitaxial growth process. During the epitaxial growth process, since a nitride semiconductor layer is not grown in a region covered by the dielectric layer 104a, the formed second nitride semiconductor layer 110 may naturally have the trench 110a exposing the dielectric layer 104a. In other words, in this embodiment, it is not necessary to perform an etching process after forming the second nitride semiconductor layer 110 to form the trench 110a. In this way, it is possible to avoid causing the defect/damage on a surface of the first nitride semiconductor layer 102 in the process of forming the trench 110a by the etching process.

Afterwards, referring to FIG. 1D, a metal layer 112 is formed on the dielectric layer 104a. A material of the metal layer 112 is, for example, Ti, Al, or a combination thereof. A method of forming the metal layer 112 is, for example, forming a metal material layer on the second nitride semiconductor layer 110 and filling the trench 110a, and then patterning the metal material layer. When the nitride semiconductor device to be formed is the transistor, the metal layer 112 may be used as a source/drain in the transistor. In this embodiment, since a thickness of the dielectric layer 104a does not exceed 2 nm, the metal layer 112 may form an ohmic contact with the first nitride semiconductor layer 102. In addition, since the first nitride semiconductor layer 102 under the dielectric layer 104a has the smooth surface, that is, there is no defect/damage on the surface, an occurrence of a dangling bond may be effectively reduced (or even avoided), thereby maintaining the performance of a formed nitride semiconductor device.

In addition, when the nitride semiconductor device to be formed is the transistor, a subsequent manufacturing process may be performed to form a gate on the second nitride semiconductor layer 110 between the two metal layers 112. The subsequent manufacturing process is well known to those skilled in the art, and will not be further described here.

Hereinafter, a nitride semiconductor device of the disclosure will be described by taking FIG. 1D as an example. Referring to FIG. 1D, in this embodiment, the nitride semiconductor device of the disclosure includes the substrate 100, the first nitride semiconductor layer 102, the second nitride semiconductor layer 110, the metal layer 112, and the dielectric layer 104a. The first nitride semiconductor layer 102 is disposed on the substrate 100. The second nitride semiconductor layer 110 is disposed on the first nitride semiconductor layer 102 and has the trench 110a. The metal layer 112 is disposed in the trench 110a. The dielectric layer 104a is disposed in the trench 110a, and is located between the metal layer 112 and the first nitride semiconductor layer 102. Since the thickness of the dielectric layer 104a does not exceed 2 nm, the metal layer 112 may form the ohmic contact with the first nitride semiconductor layer 102.

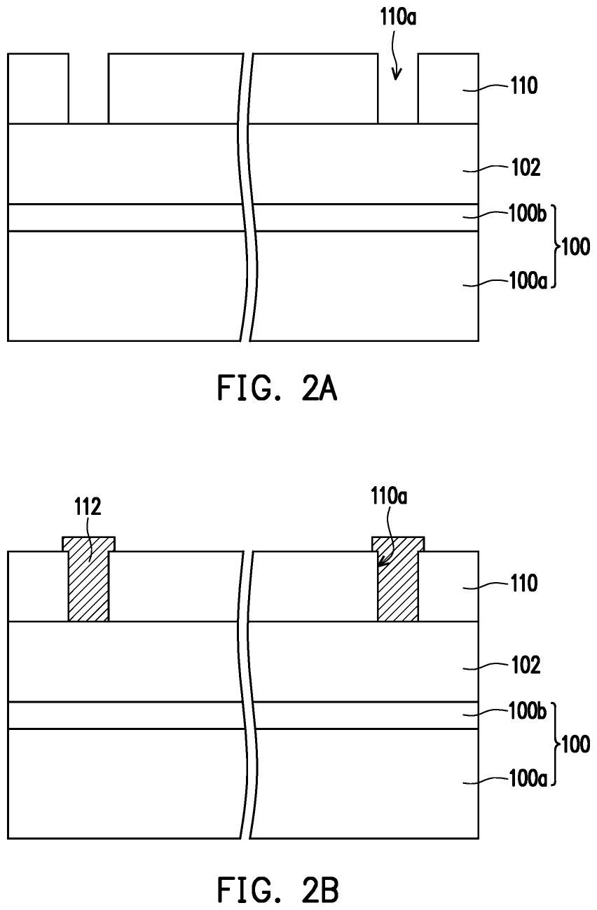

FIGS. 2A to 2B are schematic cross-sectional views of a manufacturing process of a nitride semiconductor device according to the second embodiment of the disclosure. In this embodiment, the same components as those in the first embodiment will be denoted by the same reference numerals, and the description thereof will not be repeated.

First, referring to FIG. 2A, after the steps described in FIG. 1C, the dielectric layer 104a is removed. A method of removing the dielectric layer 104a is, for example, the wet etching process, so as to avoid causing the defect/damage on the surface of the first nitride semiconductor layer 102 under the dielectric layer 104a.

Afterwards, referring to FIG. 2B, the metal layer 112 is formed in the trench 110a. In the nitride semiconductor device of this embodiment, the metal layer 112 directly contacts the first nitride semiconductor layer 102 under the trench 110a to form the ohmic contact. In addition, since the surface of the first nitride semiconductor layer 102 in contact with the metal layer 112 is covered by the dielectric layer 104a during the manufacturing process without being damaged, there is no defect/damage on the surface, and the occurrence of the dangling bond may be effectively reduced (or even avoided), thereby maintaining the performance of the formed nitride semiconductor device.

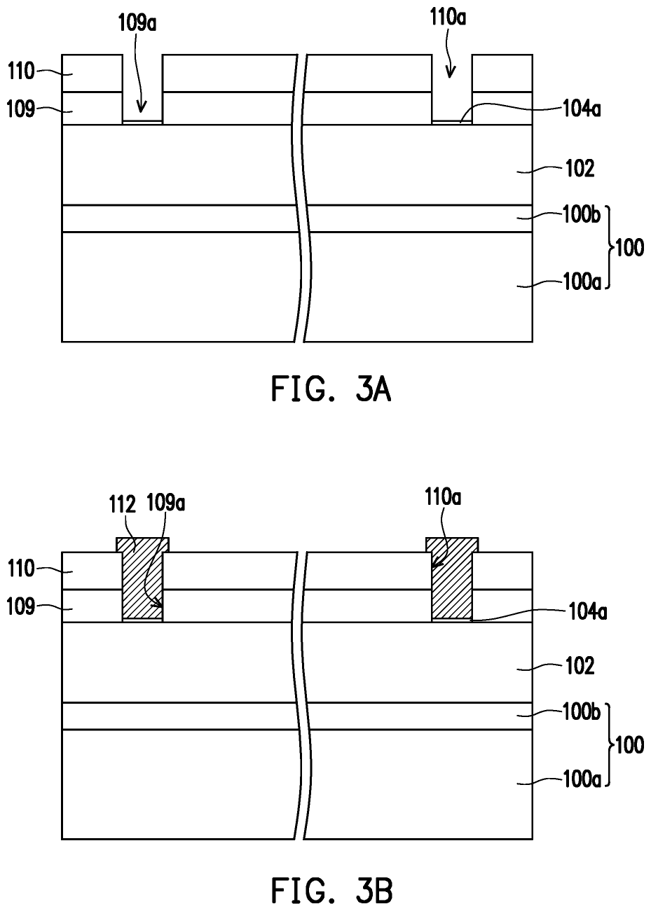

FIGS. 3A to 3B are schematic cross-sectional views of a manufacturing process of a nitride semiconductor device according to the third embodiment of the disclosure. In this embodiment, the same components as those in the first embodiment will be denoted by the same reference numerals, and the description thereof will not be repeated.

First, referring to FIG. 3A, after the steps described in FIG. 1B, the patterned photoresist layer 106 is removed. Then, in order to ensure that the second nitride semiconductor layer 110 may be formed on the smooth surface, a third nitride semiconductor layer 109 is grown on the first nitride semiconductor layer 102. The third nitride semiconductor layer 109 has a trench 109a exposing the dielectric layer 104a. A material of the third nitride semiconductor layer 109 is, for example, GaN. When the nitride semiconductor device to be formed is the transistor, the third nitride semiconductor layer 109 may be used as the channel layer in the transistor together with the first nitride semiconductor layer 102. In detail, in this embodiment, a method of forming the third nitride semiconductor layer 109 is, for example, the epitaxial growth process. During the epitaxial growth process, since the nitride semiconductor layer is not grown in the region covered by the dielectric layer 104a, the formed third nitride semiconductor layer 109 may naturally have the trench 109a exposing the dielectric layer 104a. Then, the second nitride semiconductor layer 110 is grown on the third nitride semiconductor layer 109. Similarly, during the epitaxial growth process of forming the second nitride semiconductor layer 110, since the nitride semiconductor layer is not grown in the region covered by the dielectric layer 104a, the trench 110a of the second nitride semiconductor layer 110 may naturally communicate with the trench 109a to expose the dielectric layer 104a.

Afterwards, referring to FIG. 3B, the metal layer 112 is formed in the trench 109a and the trench 110a. In this embodiment, since the thickness of the dielectric layer 104a does not exceed 2 nm, the metal layer 112 may form the ohmic contact with the first nitride semiconductor layer 102. In addition, since the first nitride semiconductor layer 102 under the dielectric layer 104a has the smooth surface, that is, there is no defect/damage on the surface, the occurrence of the dangling bond may be effectively reduced (or even avoided), thereby maintaining the performance of the formed nitride semiconductor device.

In another embodiment, after the steps described in FIG. 3A, as in the second embodiment, the dielectric layer 104a may be removed, and then the metal layer 112 is formed in the trench 109a and the trench 110a, so that the metal layer 112 directly contacts the first nitride semiconductor layer 102 under the trench 109a and the trench 110a to form the ohmic contact. In addition, since the surface of the first nitride semiconductor layer 102 in contact with the metal layer 112 is covered by the dielectric layer 104a during the manufacturing process without being damaged, there is no defect/damage on the surface, and the occurrence of the dangling bond may be effectively reduced (or even avoided), thereby maintaining the performance of the formed nitride semiconductor device.

Although the disclosure has been described with reference to the above embodiments, they are not intended to limit the disclosure. It will be apparent to one of ordinary skill in the art that modifications to the described embodiments may be made without departing from the spirit and the scope of the disclosure. Accordingly, the scope of the disclosure will be defined by the attached claims and their equivalents and not by the above detailed descriptions.

What is claimed is:

1. A nitride semiconductor device, comprising:
a substrate;
a first nitride semiconductor layer disposed on the substrate;
a second nitride semiconductor layer disposed on the first nitride semiconductor layer and having a trench, wherein the trench exposes a part of the first nitride semiconductor layer;
a metal layer disposed in the trench; and
a dielectric layer disposed in the trench and located between the metal layer and the first nitride semiconductor layer.

2. The nitride semiconductor device according to claim 1, wherein a thickness of the dielectric layer does not exceed 2 nm.

3. The nitride semiconductor device according to claim 1, wherein a material of the dielectric layer comprises Al₂O₃, SiN, SiO₂, or a combination thereof.

4. The nitride semiconductor device according to claim 1, wherein a material of the metal layer comprises Ti, Al, or a combination thereof.

5. The nitride semiconductor device according to claim 1, wherein a material of the first nitride semiconductor layer comprises GaN.

6. The nitride semiconductor device according to claim 1, wherein a material of the second nitride semiconductor layer comprises AlGaN.

7. The nitride semiconductor device according to claim 1, further comprising a third nitride semiconductor layer disposed between the first nitride semiconductor layer and the second nitride semiconductor layer.

8. The nitride semiconductor device according to claim 7, wherein a material of the third nitride semiconductor layer comprises GaN.

9. A manufacturing method of a nitride semiconductor device, comprising:
forming a first nitride semiconductor layer on a substrate;
forming a dielectric layer on the first nitride semiconductor layer;
growing a second nitride semiconductor layer on the first nitride semiconductor layer, wherein the second nitride semiconductor layer has a trench exposing the dielectric layer; and
forming a metal layer on the trench.

10. The manufacturing method of the nitride semiconductor device according to claim 9, wherein a thickness of the dielectric layer does not exceed 2 nm.

11. The manufacturing method of the nitride semiconductor device according to claim 9, wherein a material of the dielectric layer comprises Al₂O₃, SiN, SiO₂, or a combination thereof.

12. The manufacturing method of the nitride semiconductor device according to claim 9, wherein a material of the metal layer comprises Ti, Al, or a combination thereof.

13. The manufacturing method of the nitride semiconductor device according to claim 9, wherein a material of the first nitride semiconductor layer comprises GaN.

14. The manufacturing method of the nitride semiconductor device according to claim 9, wherein a material of the second nitride semiconductor layer comprises AlGaN.

15. The manufacturing method of the nitride semiconductor device according to claim 9, wherein after forming the dielectric layer and before forming the second nitride semiconductor layer, the manufacturing method further comprises forming a third nitride semiconductor layer on the substrate, and the third nitride semiconductor layer has a trench exposing the dielectric layer.

16. The manufacturing method of the nitride semiconductor device according to claim 15, wherein a material of the third nitride semiconductor layer comprises GaN.

17. The manufacturing method of the nitride semiconductor device according to claim 9, wherein after forming the second nitride semiconductor layer and before forming the metal layer, the manufacturing method further comprises removing the dielectric layer.

18. The manufacturing method of the nitride semiconductor device according to claim 17, wherein a method of removing the dielectric layer comprises a wet etching process.

19. The manufacturing method of the nitride semiconductor device according to claim 17, wherein a method of forming the dielectric layer comprises:
forming a dielectric material layer on the first nitride semiconductor layer;
patterning the dielectric material layer by using a wet etching process.

20. The manufacturing method of the nitride semiconductor device according to claim 9, wherein a method of forming the dielectric layer comprises:
forming a dielectric material layer on the first nitride semiconductor layer;
patterning the dielectric material layer by using a dry etching process.
